(19) United States
(12) Patent Application Publication
(10) Pub. No.: US 2025/0285926 A1
(43) Pub. Date: Sep. 11, 2025

(54) CORE JOINING FOR EMBEDDED DIE WITHIN PACKAGE SUBSTRATES

(71) Applicant: Intel Corporation, Santa Clara, CA (US)

(72) Inventors: Benjamin Duong, Phoenix, AZ (US); Tolga Acikalin, San Jose, CA (US); Soham Agarwal, Chandler, AZ (US); Jeremy Ecton, Gilbert, AZ (US); Kari Hernandez, Phoenix, AZ (US); Brandon Marin, Gilbert, AZ (US); Pratyush Mishra, Tempe, AZ (US); Pratyasha Mohapatra, Hillsboro, OR (US); Srinivas Pietambaram, Chandler, AZ (US); Marcel Said, Beaverton, OR (US)

(73) Assignee: Intel Corporation, Santa Clara, CA (US)

(21) Appl. No.: 18/596,547

(22) Filed: Mar. 5, 2024

(51) Int. Cl. H01L 23/15; H01L 23/522; H01L 23/538

(52) U.S. Cl. CPC H01L 23/15; H01L 23/5223; H01L 23/5384

(57) ABSTRACT

IC device package including an IC die embedded within a package substrate comprising two or more substrate cores. A cutout in a first substrate core exposes a surface of a second substrate core and an IC die is placed within the opening. A package metallization routing structure including conductive vias adjacent to the embedded IC die may be built up and terminate interconnect interfaces. One or more additional IC dies may be assembled with the package substrate, coupling the additional IC dies with the embedded IC die. In some examples, the embedded IC die comprises capacitors implementing a package-level voltage regulator.

### BACKGROUND

In electronics manufacturing, IC packaging is a stage of semiconductor device fabrication in which an IC that has been fabricated on a chip (or die) comprising a semiconducting material is assembled into a “package” that can protect the IC chip from physical damage and support electrical interconnects that couple the IC to a scaled host component, such as a package substrate, or a printed circuit board. Multiple chips can be co-assembled, for example, into a multi-chip package (MCP).

Advanced IC die packages may place additional demands on power delivery architectures. A power delivery architecture may include one or more voltage regulators (VRs) to scale voltages down from a system level (e.g., 12V) to a packaged IC die level (e.g., ˜0.5-1.5V). It is advantageous for such voltage reduction to occur as near to an IC die as possible, for example to reduce losses associated with elevated current levels needed at lower voltages. Accordingly, it may be advantageous to integrate one or more VRs within a package, particularly a multi-chip package where power demands become compounded. An IC die including passive and/or active devices supporting the integration of a VR into the package may, for example, be embedded within the package.

Advanced IC die packages may also place additional demands on electrical interconnects. Package electrical interconnection between multiple IC dies is important to ensure highest device performance as die-to-die bandwidth is often significantly higher than die-to-host bandwidth. An IC die may, for example, be embedded within a package to provide die-to-die interconnection at higher densities than the package routing that surrounds the embedded interconnect die.

These examples of advanced packaging rely on successfully embedding an IC die, which can be challenging, in part, because of height mismatch between the IC die to be embedded and the package structure within which the IC die is to be embedded. Some height mismatch may be attributable to package preforms, such as substrate cores, that have some total thickness variation (TTV). Some height mismatch may also be attributable to variation in a height or depth of a recess or cavity formed within a package preform to accommodate an embedded IC die.

Accordingly, alternative packaging architectures comprising an embedded IC die may be commercially advantageous.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 illustrates a flow diagram of methods for forming an IC die package including an IC die embedded within a substrate core stack, in accordance with some embodiments;

FIG. 2A illustrates a plan view of a workpiece comprising a first substrate core, in accordance with some embodiments;

FIG. 2B illustrates a cross-sectional view of the workpiece illustrated in FIG. 2A, in accordance with some embodiments;

FIG. 3A illustrates a plan view of cutouts formed in the first substrate core, in accordance with some embodiments;

FIG. 3B illustrates a cross-sectional view of the workpiece illustrated in FIG. 3A, in accordance with some embodiments;

FIG. 4A illustrates a plan view of a workpiece comprising a second substrate core, in accordance with some embodiments;

FIG. 4B illustrates a cross-sectional view of the workpiece illustrated in FIG. 4A, in accordance with some embodiments;

FIG. 5A illustrates a plan view of a first substrate core fused with a second substrate core into a core stack, in accordance with some embodiments;

FIG. 5B illustrates a cross-sectional view of the workpiece illustrated in FIG. 5A, in accordance with some embodiments;

FIG. 6A illustrates a plan view of embedding IC die within a core stack, in accordance with some embodiments;

FIG. 6B illustrates a cross-sectional view of the workpiece illustrated in FIG. 6A, in accordance with some embodiments;

FIG. 7 illustrates an expanded cross-sectional view of the IC die illustrated in FIG. 6A, in accordance with some embodiments;

FIG. 8A illustrates a plan view of planarizing a workpiece comprising an IC die embedded within a core stack, in accordance with some embodiments;

FIG. 8B illustrates a cross-sectional view of the workpiece illustrated in FIG. 8A, in accordance with some embodiments;

FIG. 9 illustrates a flow diagram of methods for forming an IC die package including an IC die embedded within a stacked core, in accordance with some embodiments;

FIG. 10A illustrates a plan view depicting the formation of through vias in a workpiece comprising a core stack, in accordance with some embodiments;

FIG. 10B illustrates a cross-sectional view of the workpiece illustrated in FIG. 10A, in accordance with some embodiments;

FIG. 11A is a plan view illustrating a build-up of package metallization levels on at least one side of a core stack, in accordance with some embodiments;

FIG. 11B is a cross-sectional view of the workpiece illustrated in FIG. 11A, in accordance with some embodiments including package metallization levels built-up on two opposite sides of a core stack;

FIG. 12 illustrates a cross-sectional view illustrating one package substrate including an IC die embedded within a core stack, in accordance with some embodiments;

FIG. 13 illustrates a cross-sectional view of multiple IC die coupled to the package substrate illustrated in FIG. 12, in accordance with some embodiments;

FIG. 14 illustrates a mobile computing platform or a data server machine employing a package comprising an IC die embedded within a core stack, in accordance with some embodiments; and

FIG. 15 is a functional block diagram of an electronic computing device, in accordance with some embodiments.

### DETAILED DESCRIPTION OF EXEMPLARY EMBODIMENTS

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

IC package structures including an IC die embedded within a package substrate core stack are described herein. Two or more substrate cores may be fused or bonded together into the core stack. A first core is advantageously of a thickness substantially equal to the thickness of an IC die that is to be embedded within the core stack, or is otherwise a good thickness match with the IC die thickness. A cutout (or large through hole) sufficiently large to accommodate the IC die may be formed into the first substrate core. The first substrate core may be fused or bonded with a second substrate core of any desired thickness and IC die positioned within the cutout in the first substrate core. Package dielectric and metallization features (e.g., comprising a redistribution layer (RDL)) may be formed on one or more sides of the core stack. Accordingly, packaging dielectric(s) may be applied adjacent to, and over, the embedded die. After building up the package, additional IC die may be attached, and the package assembled to a host component.

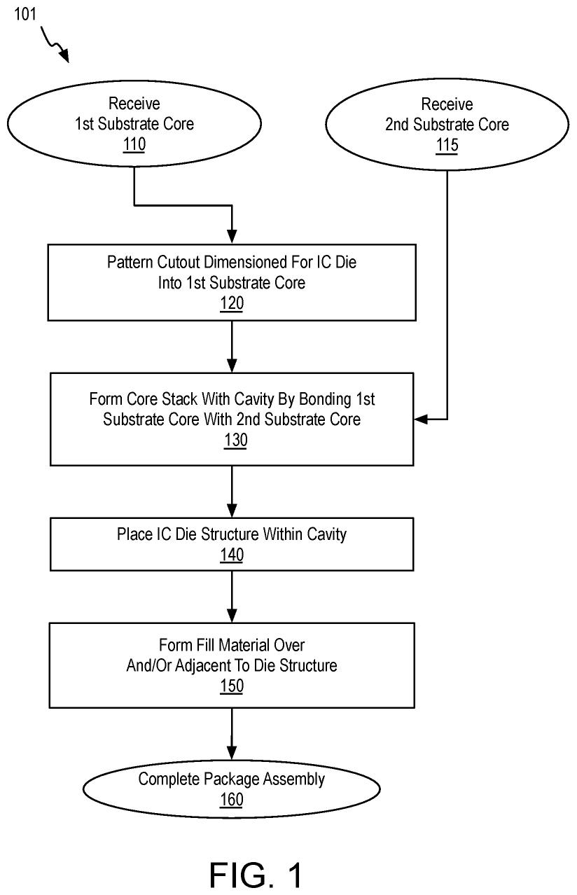

A variety of fabrication methods may be practiced to fabricate multi-chip device structures having one or more of the features or attributes described herein. FIG. 1 illustrates a flow diagram of methods 101 for forming an IC die package including an IC die embedded within a substrate core stack, in accordance with some exemplary embodiments.

Methods 101 begin at input 110 with the receipt of a first substrate core preform that has been fabricated upstream of methods 101. In methods 101, the first substrate core preform is to be fused, bonded, or otherwise joined into a stack with at least one other core preform. The first substrate core preform is advantageously thickness matched to one or more IC dies that are to be embedded with a package substrate that includes the first substrate core. As used herein, “thickness matched” means the first substrate core has a thickness (e.g., by cutting, grinding and/or polishing) predetermined to ensure a surface of an IC die having another predetermined thickness is at a desired height relative to a surface of the package substrate. As described further below, an IC die of a predetermined thickness may have a surface that is substantially coplanar with a surface of the first substrate core when the IC die is positioned within a package substrate comprising the first substrate core.

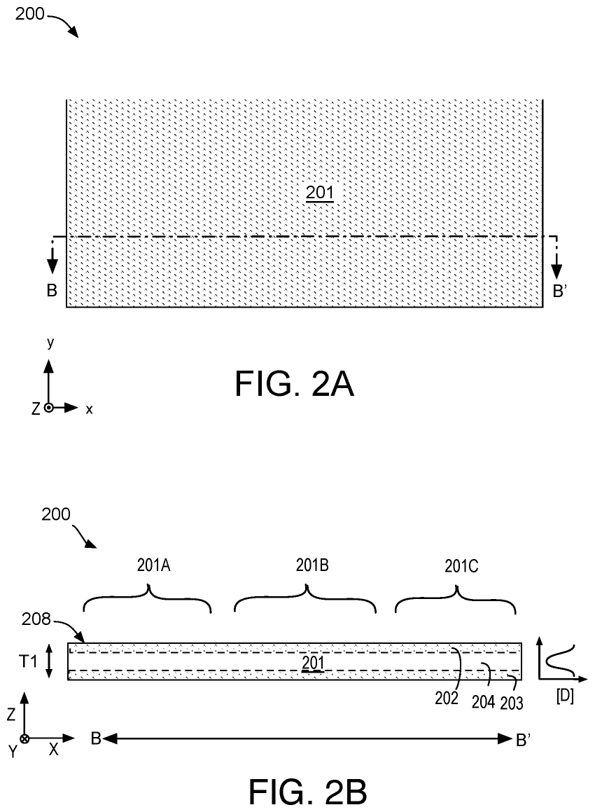

FIG. 2A illustrates a plan view of a workpiece 200 comprising a first substrate core 201, in accordance with some embodiments. Workpiece 200 may have a working surface (e.g., within the x-y plane) of any area suitable for high volume manufacturing. In some embodiments, workpiece 200 is approximately the size of a typical silicon wafer (e.g., 300-450 mm diameter). In other embodiments, workpiece 200 is a rectilinear panel having any x-axis and y-axis dimensions suitable for large format panel processing.

As shown, FIG. 2B illustrates a cross-sectional view of workpiece 200 along the B-B′ line shown in FIG. 2A, in accordance with some embodiments. In the example shown, workpiece 200 is apportionable into a plurality of package substrate regions, portions, or areas 201A, 201B, and 201C. As described further below, each of substrate regions 201A-201C may have a length (e.g., in at least the x-dimension) of 200 μm to 100 mm, or more. Substrate core 201 has a total core thickness T1 between opposite sides. Core thickness T1 may be between 50 μm and 1.4 mm, for example. In some embodiments, core thickness T1 is more specifically between 100μand 800 μm.

In some embodiments, substrate core 201 is a bulk material. Chemical composition of the bulk material may vary. Substrate core 201 may be substantially pure silicon, or a ceramic, for example. In some advantageous embodiments however, substrate core 201 is a single piece of bulk glass. Glass may be advantageously processed to a flatness comparable to that of a silicon wafer. For example, surface 208 advantageously has an RMS roughness of no more than 50 nm.

Substrate core 201 may be predominantly silica (e.g., silicon and oxygen) and may further include one or more compositional additives, such as, aluminum, beryllium, magnesium, calcium, strontium barium, radium, tin, sodium, silver potassium, boron, phosphorus, zirconium, lithium, titanium, or zinc. Substrate core 201 may therefore be any of aluminosilicate, borosilicate, alumino-borosilicate, or silica etc. Substrate core 201 may be primarily silicon, oxygen, and aluminum, for example. In some advantageous embodiments, substrate core 201 is glass comprising at least 23 weight percent silicon and at least 26 weight percent oxygen, and further comprising at least 5 weight percent aluminum.

Chemical composition of substrate core 201 may be substantially homogeneous, or not. Core 201 may have nanosized aggregates of a different composition than a remainder of the bulk, for example. Core 201 may also have a varying compositional profile across core thickness T1. FIG. 2B, for example, illustrates two surface thicknesses or zones 202 and 203. Either (or both) of surface zones 202, 203 may have a different chemical composition than a remainder (e.g., center thickness or zone 204) of substrate core 201. Surface zones 202, 203 may each have a thickness corresponding to up 20% of core thickness T1,for example. As illustrated in the dopant profile of FIG. 2B, surface zone 202 and/or surface zone 203 has a higher concentration of one or more dopants D than the center zone 204 proximal to the half substrate thickness (T1/2). Dopants D may be in the form of atomic ions or molecular ions (i.e., ion-exchange doping). Dopants D may, for example, increase the hardness of surface zones 202 and/or 203. Although the surface zone dopants may be any of those described above, in some exemplary embodiments surface zone 202 and/or 203 has more of K, Na, or Ag than center zone 204.

In exemplary embodiments, substrate core 201 is substantially amorphous, but may alternatively have an ordered nanostructure or microstructure. Substrate core 201 may be quartz glass, for example, having nanocrystalline, polycrystalline, or even substantially monocrystalline microstructure. Aggregates corresponding to compositional inhomogeneity may also have different microstructure than a remainder of substrate core 201.

Substrate core 201 may include one or more thin film material layers on one or both of a front side or back side of the bulk material. For example, in embodiments where substrate core 201 is other than glass (e.g., silicon or a ceramic), a thin film of silicon dioxide or silicon nitride may be on either a front or back surface of substrate core 201 (e.g., corresponding to surface zone 202 and/or surface zone 203).

Returning to FIG. 1, methods 101 continue at block 120 where openings, cutouts or holes are formed through the total thickness of the first core substrate. Although illustrated as part of methods 101, block 120 may alternatively be performed upstream of methods 101 such that the first core substrate is a preform both with a predetermined target thickness and having one or more cutouts. Cutouts may be formed according to any technique(s) known to be suitable for the chemical composition of the first core substrate. For example, one or more of laser ablation, mechanical drilling, and/or chemical etching may be practiced at block 120.

At least one cutout formed at block 120 has dimensions sufficient to accommodate one or more IC die within the cutout. One or more such cutouts may be formed at block 120. Additional through holes, for example having smaller dimensions suitable for conductive through vias may also be formed at block 120. If formed, smaller dimensioned through holes may be filled with conductive material (e.g., with a copper plating process) such that the core preform further includes through-core electrically conductive routes.

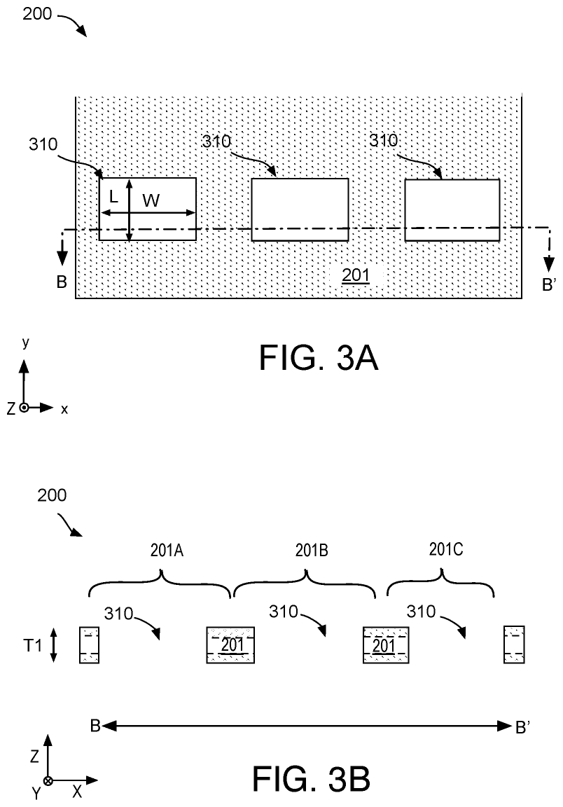

FIG. 3A illustrates a plan view of workpiece 200, which further includes cutouts or openings 310 passing through substrate core 201, in accordance with some embodiments. FIG. 3B illustrates a cross-sectional view of workpiece 200 along the B-B′ line illustrated in FIG. 3A, in accordance with some embodiments. In the illustrated example, one opening 310 is within each of package substrate areas 201A, 201B and 201C. However, more than one opening 310 may be formed within an area that corresponds with a single package substrate. Opening 310 has a length L (e.g., y-dimension) and a width W (e.g., x-dimension) at least exceeding an edge length of an IC die that is to be embedded within a package substrate. In some embodiments, length L is within a range of 200 μm to 20 mm and width W is also with a range of 200 μm to 20 mm. As shown in FIG. 3B, Each opening 310 extends through an entirely of total core thickness T1.

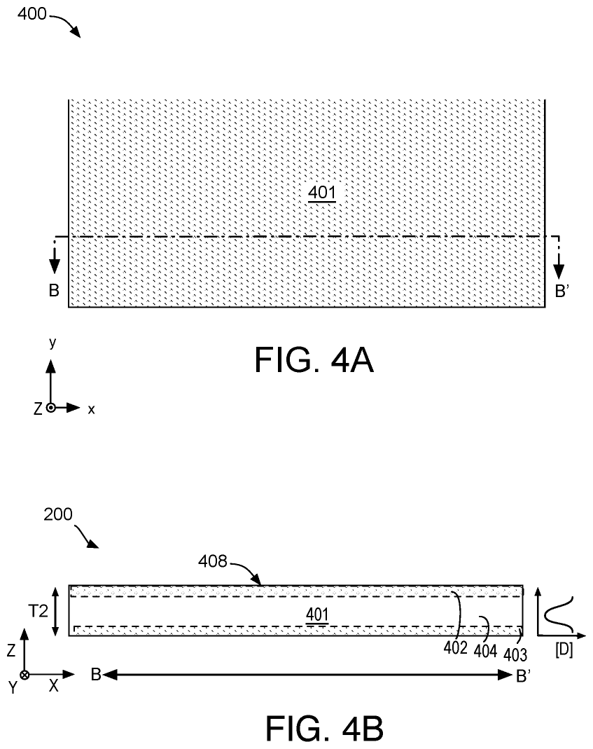

Returning to FIG. 1, methods 101 continue with the receipt of a second substrate core at input 115. At block 130 the substrate core received at input 110 is joined with the substrate core received at input 115 into a substrate core stack. FIG. 4A illustrates a plan view of a workpiece 400 comprising a second substrate core 401, in accordance with some embodiments. FIG. 4B illustrates a cross-sectional view of workpiece 400 along the B-B′ line shown in FIG. 4A, in accordance with some embodiments.

Workpiece 400 may have a working surface (e.g., within the x-y plane) of any area suitable for high volume manufacturing. In some embodiments, workpiece 400 is approximately the size of a typical silicon wafer (e.g., 300-450 mm diameter). In other embodiments, workpiece 400 is a rectilinear panel having any x-axis and y-axis dimensions suitable for large format panel processing. Workpiece 400 may be approximately the same dimensions as workpiece 200 (FIG. 2A), for example. As shown in FIG. 4B, substrate core 401 has a total core thickness T2 between opposite sides. Core thickness T2 may be any thickness, for example to ensure adequate mechanical support of a core stack further including substrate core 201 (FIG. 2B). In exemplary embodiments, core thickness T2 (FIG. 4B) is between 50 μm and 3 mm. In some embodiments, core thickness T2 is greater than core thickness T1 (FIG. 2B).

Substrate core 401 may also be a bulk material, the chemical composition of which may vary. In advantageous embodiments, substrate core 401 has substantially the same composition as substrate core 201 (FIG. 2A), which ensures good match of material properties between substrate cores 201 and 401. Accordingly, substrate core 401 may also be substantially pure silicon, or a ceramic, for example. However, in some advantageous embodiments, substrate core 401 is a single piece of bulk glass. Glass may be advantageously processed to have a surface flatness comparable to that of a silicon wafer. For example, core surface 408 advantageously has an RMS roughness of no more than 50 nm.

In some embodiments, substrate core 401 is predominantly silica (e.g., silicon and oxygen) and may further include one or more compositional additives, such as aluminum, beryllium, magnesium, calcium, strontium barium, radium, tin, sodium, silver potassium, boron, phosphorus, zirconium, lithium, titanium, or zinc. Substrate core 401 may therefore be any of aluminosilicate, borosilicate, alumino-borosilicate, or silica, etc. Substrate core 401 may be primarily silicon, oxygen, and aluminum, for example. In some advantageous embodiments, substrate core 401 is glass comprising at least 23 weight percent silicon and at least 26 weight percent oxygen, and further comprising at least 5 weight percent aluminum.

Chemical composition of substrate core 401 may be substantially homogeneous, or not. Substrate core 401 may have nanosized aggregates of a different composition than a remainder of the bulk, for example. Substrate core 401 may also have a varying compositional profile across core thickness T2. FIG. 2B, for example, illustrates a dopant profile for substrate core embodiments including two surface thicknesses or zones 402 and 403. Either (or both) of surface zones 402, 403 may have a different chemical composition than a remainder (e.g., center thickness or zone 404) of substrate core 401. Surface zones 402, 403 may each have a thickness corresponding to 5-20% of core thickness T2, for example. In some embodiments, surface zone 402 and/or surface zone 403 has a higher concentration of one or more dopants D than center zone 404. Such dopants may, for example, increase the hardness of surface zones 402 and/or 403. Although the surface zone dopants may be any of those described above, in some exemplary embodiments surface zone 402 and/or 403 has more of K, Na, or Ag than center zone 404 proximal to the half core thickness (T2/2). In some embodiments, the composition of surface zones 402 and 403 is substantially the same as that of surface zone 202 and 203 in substrate core 201 (FIG. 2B).

Substrate core 401 may be substantially amorphous, or alternatively have an ordered nanostructure or microstructure. Substrate core 401 may be quartz glass, for example, having nanocrystalline, polycrystalline, or even substantially monocrystalline microstructure. Aggregates corresponding to compositional inhomogeneity may also have different microstructure than a remainder of substrate core 401.

Substrate core 401 may include one or more thin film material layers on one or both of a front side or back side of the bulk material. For example, in embodiments where substrate core 401 is other than glass (e.g., silicon or a ceramic), a thin film of silicon dioxide or silicon nitride may be on either a front or back surface of substrate core 401 (e.g., corresponding to surface zone 402 and/or surface zone 403). According to some embodiments, substrate core 401 is nearly identical to substrate core 201 with a primary difference being their respective thicknesses, T1 and T2.

Although not illustrated in FIG. 4A or FIG. 4B, substrate core 401 may be similarly processed to include conductive through vias according to any known techniques. For example, one or more of mechanical drilling, laser ablation or etching may be practiced to form through vias into which a metal (e.g., copper) or other conductive material is deposited.

Methods 101 (FIG. 1) illustrate a joining of two substrate cores into a core stack. However, three or more such cores may be similarly joined. The core joining at block 130 may with any means suitable for the cores. In some a embodiments, the cores are directly bonded together. For exemplary embodiments where two substrate cores are bulk glass, the cores may be directly fused into a single piece of glass. Depending on the features present within each of the core preforms joined, block 130 may comprise aligning features of one substrate core to features of another substrate core.

For embodiments where both substrate core 401 and substrate core 201 include conductive vias one or more of the conductive vias in one core may be aligned to intersect one or more of the conductive vias in another core such that, upon joining, a conductive route extends through a total thickness of the two substrate cores. If such conductive vias are present, bonding performed at block 130 may be referred to as hybrid bonding where a bond interface passes through both silica and metallization. Although there are many bonding process, in exemplary embodiments block 130 comprises the application of at least one of heat and pressure across an interface between two core surfaces to be joined.

In some alternative embodiments, solder features may join substrate cores 201 and 401. Such solder features may be solder balls, bumps or posts, etc., which have been applied to metallization features on a joining surface of substrate core 201 or substrate core 401. The metallization features on joining substrate surfaces that are solder bonded, may be interfaces of conductive through vias, for example. The metallization features on joining substrate surfaces that are solder bonded may also be surface pads, for example fabricated with an semi-additive substrate metallization process. For solder bonded embodiments, a dielectric underfill material may be present around the solder features, or not.

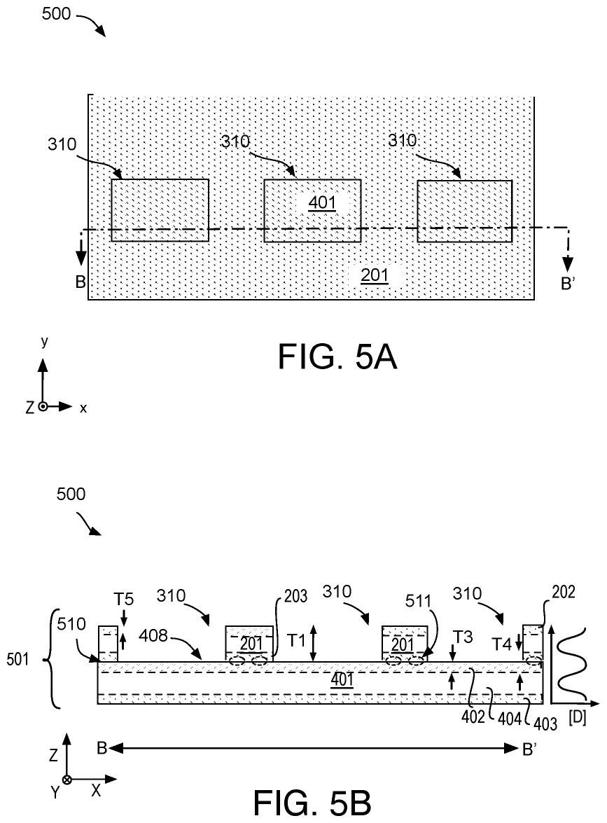

FIG. 5A illustrates a plan view of a stacked workpiece 500 comprising substrate core 201 joined to substrate core 401, in accordance with some embodiments. FIG. 5B illustrates a cross-sectional view of workpiece 500 further illustrating a core stack 501 along the B-B′ line shown in FIG. 5A. Within openings 310, core surface 408 is exposed. Upon the joining of substrate cores 201 and 401, openings 310 become recesses or cavities rather than through holes. However, because openings 310 were cutouts or through holes of a preform and core surface 408 is unaffected by the core joining, core surface 408 may advantageously retain very high surface quality (e.g., RMS roughness <50 nm). Furthermore, the depth of openings 310 is very well controlled to be precisely equal to core thickness T1 of substrate core 201.

As further illustrated in FIG. 5B, a core interface 510 is coincident, or co-planar with, core surface 408 unless cores 201 and 401 are joined by intervening solder features 511 (illustrated in dashed line as applicable to only some embodiments). For substrate cores in direct contact, core interface 510 may be visible (e.g., through SEM imaging) depending on the compositions of substrate cores 201, 401. Interface 510 may also be evident through material analysis techniques (e.g., SIMS or EELs, etc.) suitable for determining a chemical composition profile through the core stack 501. For embodiments where at least one of substrate core 201 or 401 has a surface zone with higher dopant concentration [D], core stack 501 will have a center zone of higher dopant concentration [D] corresponding to the surface zone (e.g., 203 or 402). For embodiments where substrate core 401 has surface zone 402, surface zone 402 will also be present at a bottom of openings 310. For embodiments where substrate core 201 has surface zone 203, but substrate core 401 lacks surface zone 402, surface zone 402 will be absent from the bottom of openings 310.

For embodiments where both substrate cores 201 and 401 have surface zones of higher dopant concentration [D], surface zone 402 interfaces with surface zone 203, forming a composite center zone within regions of core stack 501. The composite of zones 203 and 402 is indicative of methods where two cores are joined. For some embodiments, a dopant zone of lesser thickness T3 is at the bottom of openings 310 while a dopant zone of greater thickness T4 is within regions beyond openings 310. For embodiments where substrate core 201 includes both surface zones 202 and 203, thickness T4 may be significantly greater than thickness T5 of surface zone 202. In some embodiments, for example, thickness T4 is approximately twice the thickness T5.

For embodiments where substrate cores 201 and 401 both lack any surface zones of distinct composition, precise control of thickness T1 over the plurality of openings 310, as well as low surface roughness of core surface 408, indicates core stack 501 comprises a plurality of substrate cores.

Returning to FIG. 1, methods 101 continue at block 140 where one or more IC die are placed within a recess or cavity of a substrate core stack. Each IC die may be positioned adjacent to sidewalls of a first substrate core and adhered to a surface of an underlying substrate core. Any adhesive or bond film known to be suitable for die attach (e.g., a thermoset) may be employed to hold the IC die upon a surface of a substrate core. In some examples, at block 140 a pick-and-place machine positions IC dies on patches of adhesive present at the bottom of a cavity. The adhesive may then be activated and/or cured (e.g., from a b-staged material).

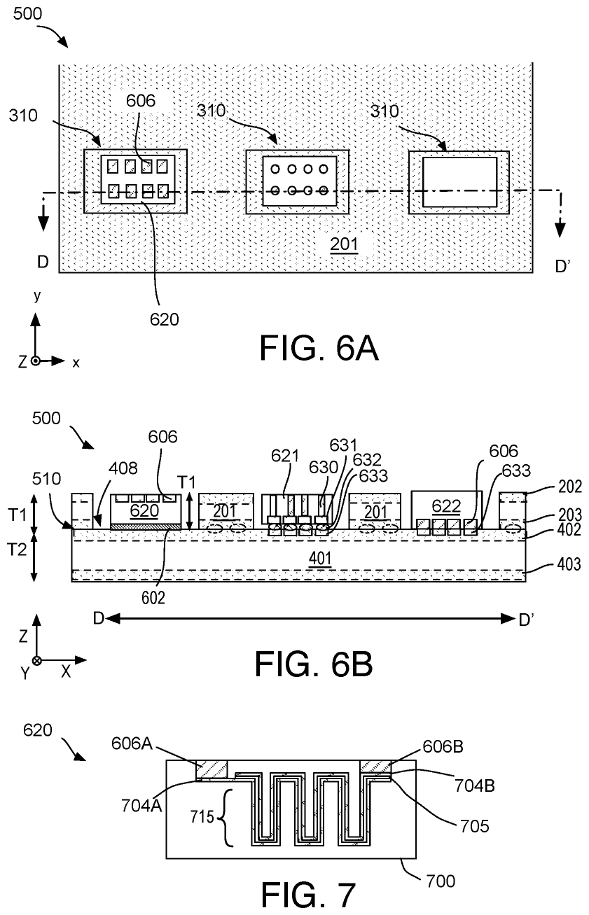

FIG. 6A illustrates a plan view of IC die 620 placed within openings 310 of workpiece 500, in accordance with some embodiments. FIG. 6B illustrates a cross-sectional view of workpiece 500 along the B-B′ line shown in FIG. 6A, in accordance with some embodiments. As illustrated, an adhesive 602 may be between core surface 408 and a surface of IC die 620. Although adhesive 602 may have any composition suitable for die attach, in some examples adhesive 602 comprises a die-attach film (DAF), an epoxy, or a solder. In other embodiments, adhesive 602 may be absent with IC die 620 instead directly bonded to core surface 408. A sidewall edge of IC die 620 is laterally adjacent to a sidewall edge of substrate core 201. The size of a gap between an edge sidewall of IC die 620 and a nearest sidewall of substrate core 201 may vary, for example according to the precision of IC die placement.

Although FIG. 6A-6B illustrate a single IC die embedded within each opening 310, any number of IC die may be similarly placed laterally adjacent to each other over different regions of the underlying core surface 408 exposed within one opening 310. In the example illustrated, IC die 620 has IC layers comprising a front side surface further comprising a metallization features 606. In some examples, IC layers comprise active and/or passive devices electrically coupled to metallization features 606. IC die 620 may be affixed to core substrate 401 “front-side up,” as shown, so that front-side metallization features 606 are distal from substrate core 401. In alternative embodiments, IC die 620 may be flip-chip assembled “front-side down” so that front-side metallization features 606 are instead proximal to substrate core 401.

As shown in FIG. 6B, IC die 620 (along with adhesive 602) has thickness Tl so that a front side surface of IC die 620 is substantially coplanar with the surrounding core surface 208 when back side die surface of IC die 620 is in contact with adhesive material 602. As used herein, “substantially coplanar” means IC die 620 and substrate core 201 surfaces are within 10 μm of being coplanar.

IC die 620 may be a fully functional ASIC or may be a chiplet or tile that has more limited functionality supplementing one or more other IC dies that are to be part of the same multi-chip device. A chiplet or tile may, for example, include only passive devices, such as one or more capacitors, inductors, or resistors. FIG. 7 illustrates an expanded cross-sectional view of IC die 620, in accordance with some embodiments where IC die includes trench capacitors 715. As shown, trench capacitors 715 are embedded within a die substrate material 700 such as, but not limited to, a predominantly silicon (e.g., substantially pure Si) material, a predominantly germanium (e.g., substantially pure Ge) material, or a compound material, for example comprising Group IV majority constituents (e.g., SiGe alloys, GeSn alloys). Within trenches formed in die substrate material 700, capacitor electrodes 704A and 704B separated by an intervening insulator 705. Individual ones of electrodes 704A, 704B are coupled to individual ones of metallization features 606A, 606B, respectively. Trench capacitors 715 may have any architecture known for an IC die and may therefore provide a capacitive array of very high density that is, in some embodiments, suitable for implementing a power supply voltage regulator.

In alternative passive embodiments, IC die 620 is an electrical interconnect bridge IC die. The bridge die may include primarily interconnect metallization, for example that has been fabricated with a back-end-of-line (BEOL) monolithic IC die manufacturing process. Such a passive IC die may merely include interconnect routing to convey electrical communication signals between different metallization features 606.

IC die 620 may also be “active” with one or more types of active devices within a die device layer that may include any semiconductor material. In some embodiments, the active devices are field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 5-30 nm. Additionally, or in the alternative, IC die 620 may include active devices other than FETs. For example, a die device layer may include electronic memory structures, spin valves, etc.

IC die 620 may comprise one or more IC die metallization levels on either side of a die substrate material. In exemplary embodiments, die metallization features 606 (i.e., 606A, 606B in FIG. 7) are embedded within an insulator. While IC die metallization features 606 may have any composition(s) of sufficient electrical conductivity, in exemplary embodiments, IC die metallization features 606 are predominantly copper (Cu). In other examples, metallization features 606 are predominantly other than Cu, such as, but not limited to predominantly Ru, or predominantly W. An uppermost one of metallization features 606 may have a feature pitch ranging from 100 nm to several microns, for example. IC die 621 illustrates another example where one or more through die substrate vias 630 intersect backside IC die metallization pads 631. Metallization pads 631 may be bonded to corresponding metallization pads 633 on core substrate 401 through a solder feature 632. Alternatively, and as illustrated for IC die 622 that illustrates a flip-chip orientation, metallization features 606 may be directly (hybrid) bonded to core 401 and metallization pads 633 embedded therein. Die TSVs 630 may have any architecture and generally include a metallization, such as, but not limited to, Cu. Notably, the IC die bonding variations illustrated in FIG. 6A and 6B need not be present within a single workpiece.

Returning to FIG. 1, methods 101 continue at block 150 where a material is formed over and/or around the IC die embedded within the workpiece. In some embodiments, a mold material is molded around the embedded IC die, at least partially backfilling any gap between a sidewall of the IC die and an adjacent sidewall of a substrate core. Alternatively, a wet dielectric material may be spin planarized over the workpiece and cured. Following molding or spin-on processing, the workpiece may be globally planarized, for example with any suitable chemical-mechanical polisher. Methods 101 then end with completion of a package assembly at output 160, for example where any known package build-up process(es) may be performed.

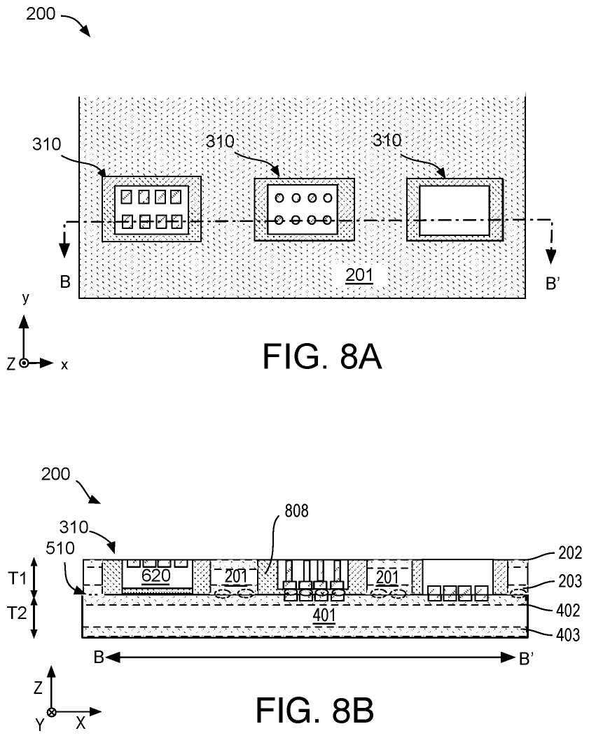

FIG. 8A and 8B illustrate plan and sectional views of a planarized workpiece 500 comprising IC die embedded within a core stack, in accordance with some embodiments. In these examples, a mold material 808 forms a frame around IC die 620 and backfills any remaining open space within openings 310. Gap width around IC die 620 may vary, for example from 100 nm to several microns. The composition of mold material 808 may vary with implementation. In some embodiments, mold material 808 is an organic material, such as an epoxy resin, phenolic-glass, or a resinous film. The epoxy resin may be, for example, an acrylate of novolac such as epoxy phenol novolacs (EPN) or epoxy cresol novolac (ECN)).

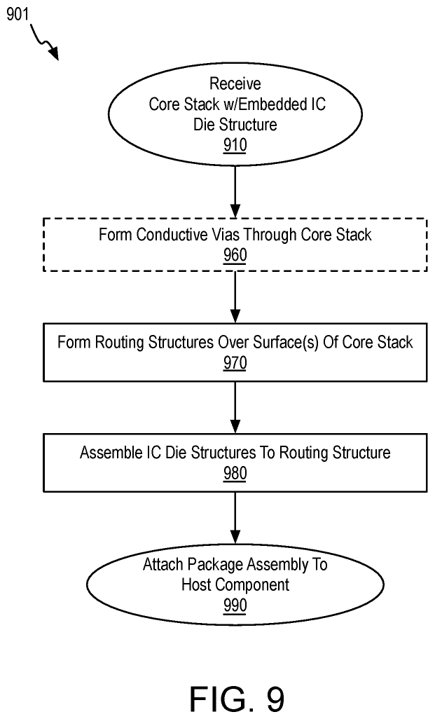

As illustrated in FIG. 8B, workpiece 500 is ready to be further processed, for example according to a semi-additive packaging build-up process. FIG. 9 illustrates a flow diagram of methods 901 for forming an IC die package including an IC die embedded within a stacked core, in accordance with some embodiments.

Methods 901 begin at input 910 where a core stack including an embedded IC die structure is received. In some embodiments, workpiece 500 is received at input 910. Alternatively, any another workpiece having an IC die similarly embedded within a stacked core may be received at input 910.

At block 960, conductive through vias may be formed through a total thickness of the core stack. Block 960 is illustrated in dashed line to emphasize formation of through vias is optional, for example because through vias may instead have been separately fabricated within individual substrate core preforms, which are then joined together into a core stack.

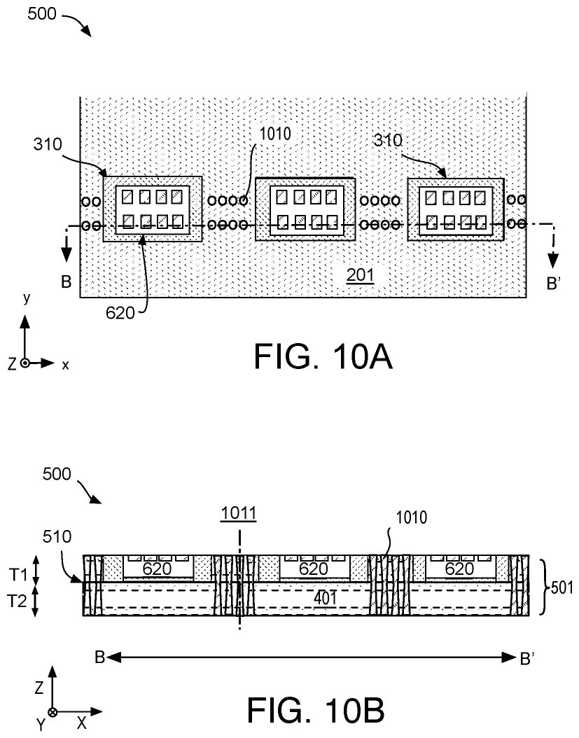

FIG. 10A and FIG. 10B are plan and sectional views depicting the formation of through vias 1010 in workpiece 500. For the sake of clarity, workpiece 500 is illustrated to include a plurality of IC die 620. Through vias may convey power into an embedded IC die comprising trench capacitors, for example. In the example illustrated, through vias 1010 have a continuous longitudinal via axis 1011 over the total thickness of core stack 501. Continuous longitudinal via axis 1011 is indicative of through vias 1010 having been formed after formation of core stack 501. In alternative embodiments, through vias are separately formed in each core preform prior to forming core stack 501. For such embodiments, non-zero misalignment during the joining of substrate cores will induce some through via misalignment along the thickness of core stack 501. Longitudinal via axis 1011 will then not be continuous as illustrated in FIG. 10B, but instead will have some lateral offset, shift, or discontinuity at interface 510. Although the longitudinal via axis may have discontinuity, such bonded or fused vias may nevertheless provide electrical continuity through core stack 501.

For a core stack including through vias, methods 901 (FIG. 9) continue at block 970 where electrical routing structures are formed over one or more of a front side and back side of the core stack to complete a package substrate. Any package routing process may be practiced at block 970, such as any semi-additive process whereby metallization is deposited and dielectric material layers are built up by depositions or laminations, for example.

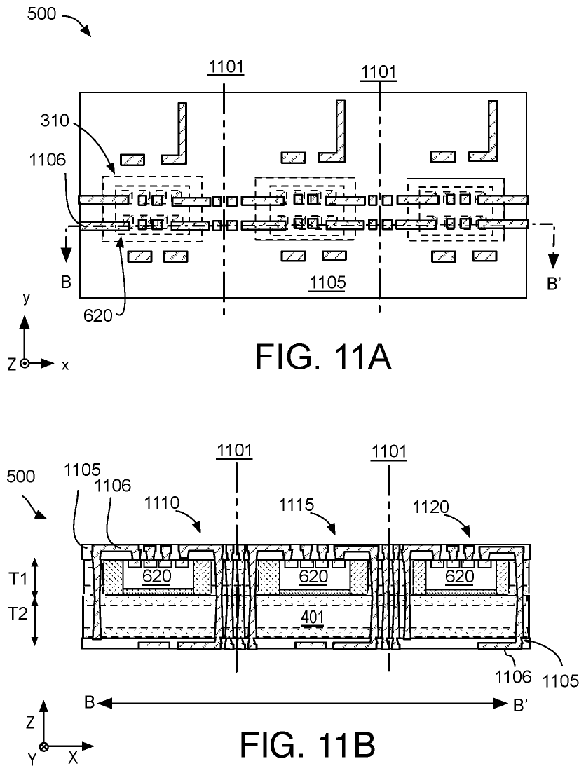

FIG. 11A is a plan view illustrating interconnect levels formed on at least one side of workpiece 500, in accordance with some embodiments. FIG. 11B is a cross-sectional view of workpiece 500, in accordance with some embodiments where interconnect levels are built-up on two opposite sides of a core stack.

In some embodiments, package dielectric material 1105 is an organic material, such as, an epoxy resin, phenolic-glass, or a resinous film such as the GX-series films commercially available from Ajinomoto Fine-Techno Co., Inc. (ABF). Package dielectric material 1105 may comprise epoxy resins (e.g., EPN or ECN). In some specific examples, package dielectric 1105 is a bisphenol-A epoxy resin, for example including epichlorohydrin. In other examples, package dielectric material 1105 includes bisphenol-F epoxy resin (with epichlorohydrin). In other examples, package dielectric material 1105 includes aliphatic epoxy resin, which may be monofunctional (e.g., dodecanol glycidyl ether), difunctional (butanediol diglycidyl ether), or have higher functionality (e.g., trimethylolpropane triglycidyl ether). In still other examples, package dielectric material 1105 includes glycidylamine epoxy resin, such as triglycidyl-p-aminophenol (functionality 3) and N,N,N′,N′-tetraglycidyl-bis-(4-aminophenyl)-methane (functionality 4).

The interconnect levels include RDL or routing metallization features 1106 embedded within package dielectric 1105. The metallization features 1106 may comprise lateral runs fanning out I/O or power to and/or from IC dies 620 and terminating at interconnect interfaces on opposite sides of workpiece 500. The number of layers and/or thicknesses of metallization features 1106 may vary according to implementation and requirements of the IC dies assembled with a particular device package. In some embodiments, each layer of metallization features 1106 is formed by first depositing a seed layer (e.g., Cu) and then forming a plating resist mask (not depicted) over the seed layer. With an electrolytic deposition process, Cu is plated upon the seed layer wherever the resist mask is absent. The building up of levels of metallization features 1106 may comprise any number of cycles with each cycle including application of an intervening layer of package dielectric material, patterning of the package dielectric material, and plating of conductive features within features patterned in the package dielectric material.

In accordance with some embodiments, interconnect features may be formed on exposed surfaces of conductive features of the package structures in preparation for assembly. A workpiece may then be singulated or disaggregated into multiple package substrates 1110, 1115 and 1120, each comprising package substrate edges 1101 that typically define rectangular prisms but may also define more complicated solid forms.

Returning to FIG. 9, methods 901 continue at block 980 where one or more IC die structures are interconnected to routing structure interface features of a package substrate. IC die assembly at block 980 may be according to any known techniques. In some examples, IC die are directly bonded to a package substrate. In other embodiments, IC die are assembled to a package substrate with solder interconnect features. IC die assembly at block 980 may be performed before or after package substrate singulation.

IC dies assembled at block 980 may receive power at least partially conditioned or supplied through one or more IC die embedded within the package substrate, for example according to any of the embodiments described elsewhere herein. IC dies assembled at block 980 may also be at least partially interconnected to each other through one or more IC die embedded within the package substrate, for example according to any of the embodiments described elsewhere herein. Methods 901 end at output 990 where the device package assembly is further assembled, for example to any suitable host component.

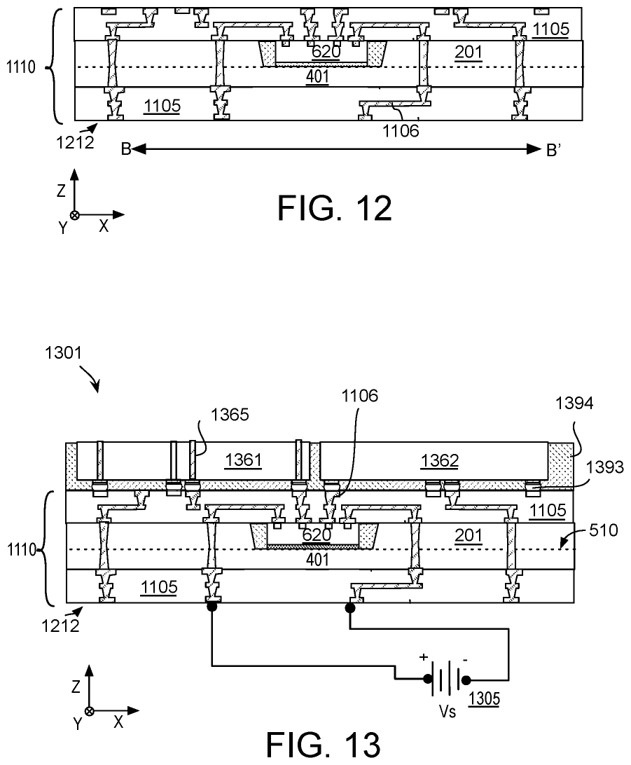

FIG. 12A illustrates a cross-sectional view of package substrate 1110 including IC die 620 embedded within a fused glass core stack, in accordance with some embodiments. As shown, package metallization 1106 couples IC die 620 to a package backside 1212. In exemplary embodiments where IC die 620 comprises capacitors, power may be coupled from any host component into IC die 620 through backside 1212.

FIG. 13 illustrates a cross-sectional view of a multi-chip package 1301 comprising IC die 1361 and 1362, which are electrically coupled to package substrate 1110, in accordance with some embodiments. IC die 1361 includes through die vias 1365 and is coupled to package substrate 1110 and/or IC die 620 in a back-to-front orientation. IC die 1362 illustrates an alternative front-to-front orientation with package substrate 1110 and/or IC die 620.

IC die 1361 and 1362 may each be any fully functional ASIC, disaggregated tile, or chiplet of lesser functionality. At least one of IC die 1361, 1362 may be any of a wireless radio circuit, microprocessor core, electronic memory circuit, floating point gate array (FPGA), power management and/or power supply circuit, or include a MEMS device. In some examples, one or more of IC die 1361, 1362 include one or more banks of active repeater circuitry to improve multi-chip interconnects (e.g., network-on-chip architectures). In other examples, one or more of IC die 1361, 1362 include clock generator circuitry or temperature sensing circuitry. In other examples, one or more of IC die 1361, 1362 include logic circuitry that implement mesh network-on-chip architectures. In still other examples, at least one of IC die 1361, 1362 includes microprocessor core circuitry, for example comprising one or more shift registers. Such microprocessor core circuitry may be part of an intelligence processing unit (IPU), graphical process unit (GPU) or central processing unit, for example. In another embodiment, at least one of IC die 1361, 1362 is a photonic IC (PIC), for example comprising one or more optical waveguides, optical multiplexer/demultiplexer, lasers and/or photodetectors.

In package 1301, IC die 1361, 1362 are interconnected to package substrate 1110 through solder interconnects 1393. In other embodiments, IC die 1361, 1362 are directly bonded (e.g., hybrid bonded) to a surface of package substrate 1110. As shown, IC die 1361, 1362 are interconnected to front side package metallization 1106, which includes metallization features further coupled to IC die 620. In some embodiments where IC die 620 comprises embedded capacitors, IC die 620 is coupled to a host power supply 1305. IC die 1361 and 1362 are further coupled to receive power from IC die 620, for example at a voltage stepped down from an output voltage of host power supply 1305. IC die 1361, 1362 include one or more I/O metallization routes further coupled to package backside 1212, which may interface to any host component (e.g., with solder interconnects).

As shown in FIG. 13, IC die 1361 are 1362 are embedded in a package dielectric 1394, which may be any mold material, for example. One or more heat spreaders and/or heat sinks (not depicted) may be further coupled to exposed surfaces of IC die 1361, 1362.

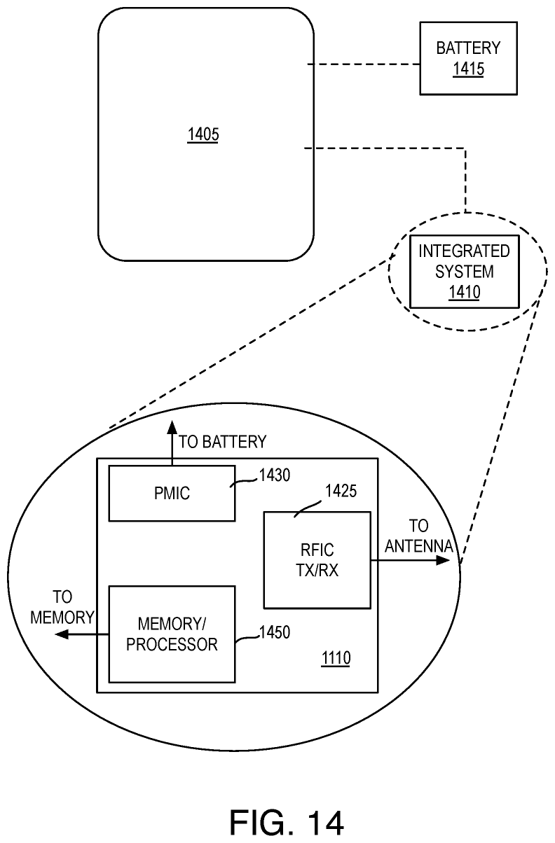

FIG. 14 illustrates a computing platform 1405. Computing platform 1405 may be any commercial server, for example including any number of high-performance computing platforms within a rack and networked together for electronic data processing, which in the exemplary embodiment includes a multi-chip package 1301, for example as described elsewhere herein. Computing platform 1405 may include an integrated or disintegrated IC die system 1410, and a battery 1415.

As illustrated in the expanded view, IC die system 1410 comprises one or more of a power management integrated circuit (PMIC) 1430 or RF (wireless) integrated circuit (RFIC) 1425 including a wideband RF (wireless) transmitter and/or receiver. IC die system 1410 further includes one or more of a memory and/or processor core 1450 assembled to a package substrate 1110. PMIC 1430 may perform battery power regulation, DC-to-DC conversion, etc., and so has an input coupled to battery 1415 and with an output providing a current supply to other functional modules. In some embodiments PMIC 1430 receives power from an embedded IC die comprising capacitors, for example embedded in a core of package substrate 1110 as described elsewhere herein. As further illustrated, in the exemplary embodiment, an RFIC 1425 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, and beyond.

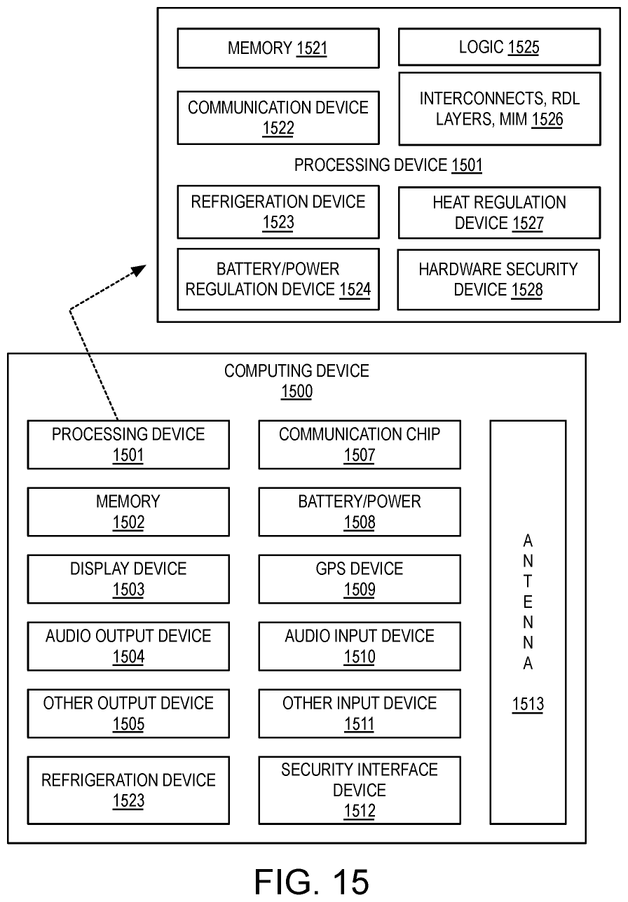

FIG. 15 is a block diagram of a cryogenically cooled computing device 1500 in accordance with some embodiments. For example, one or more components of computing device 1500 may include any of the devices or structures discussed elsewhere herein. Several components are illustrated in FIG. 15, but any one or more of these components may be omitted or duplicated, as suitable for the application. In some embodiments, some or all the components included in computing device 1500 may be attached to one or more printed circuit boards (e.g., a motherboard). In some embodiments, various ones of these components may be fabricated onto a single system-on-a-chip (SoC) die. Additionally, in various embodiments, computing device 1500 may not include one or more of the components illustrated in FIG. 15, but computing device 1500 may include interface circuitry for coupling to the one or more components. For example, computing device 1500 may not include a display device 1503, but may include display device interface circuitry (e.g., a connector and driver circuitry) to which display device 1503 may be coupled.

Computing device 1500 may include a processing device 1501 (e.g., one or more processing devices). As used herein, the term processing device or processor indicates a device that processes electronic data from registers and/or memory to transform that electronic data into other electronic data that may be stored in registers and/or memory. Processing device 1501 may include a memory 1521, a communication device 1522, a refrigeration/active cooling device 1523, a battery/power regulation device 1524, logic 1525, interconnects 1526, a heat regulation device 1527, and a hardware security device 1528.

Processing device 1501 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

Processing device 1501 may include a memory 1502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1521 includes memory that shares a die with processing device 1501. This memory may be used as cache memory and may include embedded dynamic random-access memory (eDRAM) or spin transfer torque magnetic random-access memory (STT-M RAM).

Computing device 1500 may include a heat regulation/refrigeration device 1523. Heat regulation/refrigeration device 1523 may maintain processing device 1501 (and/or other components of computing device 1500) at a predetermined low temperature during operation. This predetermined low temperature may be any temperature discussed elsewhere herein.

In some embodiments, computing device 1500 may include a communication chip 1507 (e.g., one or more communication chips). For example, the communication chip 1507 may be configured for managing wireless communications for the transfer of data to and from computing device 1500. The term “wireless” and its derivatives may be used to describe circuits, devices, systems, methods, techniques, communications channels, etc., that may communicate data through the use of modulated electromagnetic radiation through a nonsolid medium.

Communication chip 1507 may implement any wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1507 may operate in accordance with other wireless protocols in other embodiments. Computing device 1500 may include an antenna 1513 to facilitate wireless communications and/or to receive other wireless communications (such as AM or FM radio transmissions).

In some embodiments, communication chip 1507 may manage wired communications, such as electrical, optical, or any other suitable communication protocols (e.g., the Ethernet). As noted above, communication chip 1507 may include multiple communication chips. For instance, a first communication chip 1507 may be dedicated to shorter-range wireless communications such as Wi-Fi or Bluetooth, and a second communication chip 1507 may be dedicated to longer-range wireless communications such as GPS, EDGE, GPRS, CDMA, WiMAX, LTE, EV-DO, or others. In some embodiments, a first communication chip 1507 may be dedicated to wireless communications, and a second communication chip 1507 may be dedicated to wired communications.

Computing device 1500 may include battery/power circuitry 1508. Battery/power circuitry 1508 may include one or more energy storage devices (e.g., batteries or capacitors) and/or circuitry for coupling components of computing device 1500 to an energy source separate from computing device 1500 (e.g., AC line power).

Computing device 1500 may include a display device 1503 (or corresponding interface circuitry, as discussed above). Display device 1503 may include any visual indicators, such as a heads-up display, a computer monitor, a projector, a touchscreen display, a liquid crystal display (LCD), a light-emitting diode display, or a flat panel display, for example.

Computing device 1500 may include an audio output device 1504 (or corresponding interface circuitry, as discussed above). Audio output device 1504 may include any device that generates an audible indicator, such as speakers, headsets, or earbuds, for example.

Computing device 1500 may include an audio input device 1510 (or corresponding interface circuitry, as discussed above). Audio input device 1510 may include any device that generates a signal representative of a sound, such as microphones, microphone arrays, or digital instruments (e.g., instruments having a musical instrument digital interface (MIDI) output).

Computing device 1500 may include a global positioning system (GPS) device 1509 (or corresponding interface circuitry, as discussed above). GPS device 1509 may be in communication with a satellite-based system and may receive a location of computing device 1500, as known in the art.

Computing device 1500 may include another output device 1505 (or corresponding interface circuitry, as discussed above). Examples include an audio codec, a video codec, a printer, a wired or wireless transmitter for providing information to other devices, or an additional storage device.

Computing device 1500 may include another input device 1511 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1500 may include a security interface device 1512. Security interface device 1512 may include any device that provides security measures for computing device 1500 such as intrusion detection, biometric validation, security encode or decode, managing access lists, malware detection, or spyware detection.

Computing device 1500, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that practice of the disclosed techniques and architectures is not limited to the embodiments so described but can be modified and altered without departing from the scope of the appended claims. For example, the above embodiments may include specific combinations of features as further provided below.

In first examples, an apparatus comprises a first substrate core and a second substrate core in a stack with the first substrate core, a surface of the second substrate core is exposed within an opening in the first substrate core. The apparatus comprises an IC die within the opening in the first substrate core and one or more levels of metallization are over the first substrate core and coupled with the IC die.

In second examples, for any of the first examples the surface of the second substrate core exposed within the opening has an RMS roughness of no more than 50 nm.

In third examples, for any of the first through second examples a surface of the first substrate core is within 10 um of being coplanar with a surface of the IC die.

In fourth examples, for any of the first through third examples the first substrate core is in direct contact with the second substrate core, and a core interface between the first substrate core and the second substrate core is substantially coplanar with the surface of the second substrate core exposed within the opening in first substrate core.

In fifth examples, for any of the fourth examples the first substrate core comprises a first layer of glass, the second substrate core comprises a second layer of glass, and the first layer of glass is fused along the core interface to the second layer of glass.

In sixth examples, for any of the fourth through fifth examples the first substrate core is a first piece of bulk glass having a thickness of at least 50 μm, the second substrate core is a second piece of bulk glass having a thickness of at least 50 μm, and the first piece of bulk glass is fused along the core interface to the second piece of bulk glass.

In seventh examples, for any of the fifth or sixth examples a concentration of a dopant within the first substrate core is higher proximal to the core interface than at a half thickness of the first substrate, or a concentration of a dopant within the second substrate core is higher proximal to the core interface than at a half thickness of the second substrate.

In eight examples, for any of the seventh examples the concentration of the dopant within the second substrate core is higher proximal to the IC die than at the half thickness of the second substrate core.

In ninth examples, for any of the seventh through eighth examples the dopant comprises K, Na, or Ag.

In tenth examples, for any of the first through ninth examples the apparatus comprises a conductive via extending through both the first substrate core and the second substrate core.

In eleventh examples, for any of the tenth examples a longitudinal axis of the conductive via is continuous through the first substrate core and through the second substrate core.

In twelfth examples, for any of the first through eleventh examples the IC die is a first IC die and wherein the apparatus further comprises one or more second IC die coupled to the metallization.

In thirteenth examples, for any of the twelfth examples the first IC die comprises a plurality of trench capacitors and wherein the second IC die are coupled to receive power through a voltage regulator comprising the trench capacitors.

In fourteenth examples, an apparatus comprises a first IC die and a package substrate coupled to the first IC die. The package substrate comprises one or more levels of metallization between the first IC die and a second IC die embedded within the package substrate, and a glass core comprising a first thickness of glass surrounding the second IC die and a second thickness of glass fused to the first thickness of glass and under the second IC die.

In fifteenth examples, for any of the fourteenth examples a surface of the second IC die closest to the first IC die is substantially coplanar with a surface of the glass core closest to the first IC die.

In sixteenth examples, for any of the fourteenth through sixteenth examples the metallization comprises first features coupling the second IC die to a host power supply and the metallization comprises second features coupling the second IC die to the first IC die.

In seventeenth examples, for any of the fourteenth through sixteenth examples the apparatus comprises a third IC die adjacent to the first IC die, wherein the metallization comprises features coupling the second IC die to both the first IC die and the second IC die.

In eighteenth examples, a method comprises joining a first substrate core and a second substrate core, the first substrate core having an opening therein, which exposes a surface of the second substrate core. The method comprises placing an IC die within the opening. The method comprises forming one or more levels of metallization over the first substrate core and over the IC die.

In nineteenth examples, for any of the eighteenth examples the method comprises etching the opening completely through the first substrate core prior to joining the first substrate core with second substrate core.

In twentieth examples for any of the eighteenth through nineteenth examples the first substrate core is a first piece of glass, the second substrate core is a second piece of glass, and the joining comprises fusing a surface of the first piece of glass to a surface of the second piece of glass.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosed techniques and architectures should therefore be determined with reference to the appended claims, along with the full scope of equivalents to which such claims are entitled.

What is claimed is:

1. An apparatus, comprising:
a first substrate core;
a second substrate core in a stack with the first substrate core, a surface of the second substrate core exposed within an opening in the first substrate core;
an IC die within the opening in the first substrate core; and
one or more levels of metallization over the first substrate core and coupled with the IC die.

2. The apparatus of claim 1, wherein the surface of the second substrate core exposed within the opening has an RMS roughness of no more than 50 nm.

3. The apparatus of claim 1, wherein:
a surface of the first substrate core is within 10 μm of being coplanar with a surface of the IC die.

4. The apparatus of claim 1, wherein the first substrate core is in direct contact with the second substrate core, and a core interface between the first substrate core and the second substrate core is substantially coplanar with the surface of the second substrate core exposed within the opening in first substrate core.

5. The apparatus of claim 4, wherein:
the first substrate core comprises a first layer of glass;
the second substrate core comprises a second layer of glass; and
the first layer of glass is fused along the core interface to the second layer of glass.

6. The apparatus of claim 4, wherein:
the first substrate core is a first piece of bulk glass having a thickness of at least 50 μm;
the second substrate core is a second piece of bulk glass having a thickness of at least 50 μm; and
the first piece of bulk glass is fused along the core interface to the second piece of bulk glass.

7. The apparatus of claim 5, wherein:
a concentration of a dopant within the first substrate core is higher proximal to the core interface than at a half thickness of the first substrate, or
a concentration of a dopant within the second substrate core is higher proximal to the core interface than at a half thickness of the second substrate.

8. The apparatus of claim 7, wherein the concentration of the dopant within the second substrate core is higher proximal to the IC die than at the half thickness of the second substrate core.

9. The apparatus of claim 7, wherein the dopant comprises K, Na, or Ag.

10. The apparatus of claim 1, further comprising a conductive via extending through both the first substrate core and the second substrate core.

11. The apparatus of claim 10, wherein a longitudinal axis of the conductive via is continuous through the first substrate core and through the second substrate core.

12. The apparatus of claim 1, wherein the IC die is a first IC die and wherein the apparatus further comprises one or more second IC die coupled to the metallization.

13. The apparatus of claim 12, wherein the first IC die comprises a plurality of trench capacitors and wherein the second IC die is coupled to receive power through a voltage regulator comprising the trench capacitors.

14. An apparatus comprising:
a first IC die; and
a package substrate coupled to the first IC die, wherein the package substrate comprises:
one or more levels of metallization between the first IC die and a second IC die embedded within the package substrate; and
a glass core comprising a first thickness of glass surrounding the second IC die and a second thickness of glass fused to the first thickness of glass and under the second IC die.

15. The apparatus of claim 14, wherein a surface of the second IC die closest to the first IC die is substantially coplanar with a surface of the glass core closest to the first IC die.

16. The apparatus of claim 14, wherein the metallization comprises first features coupling the second IC die to a host power supply and wherein the metallization comprises second features coupling the second IC die to the first IC die.

17. The apparatus of claim 14, further comprising a third IC die adjacent to the first IC die, wherein the metallization comprises features coupling the third IC die to both the first IC die and the second IC die.

18. A method comprising:
joining a first substrate core and a second substrate core, the first substrate core having an opening therein, which exposes a surface of the second substrate core;
placing an IC die within the opening; and
forming one or more levels of metallization over the first substrate core and over the IC die.

19. The method of claim 18, further comprising etching the opening completely through the first substrate core prior to joining the first substrate core with second substrate core.

20. The method of claim 18, wherein:
the first substrate core is a first piece of glass;
the second substrate core is a second piece of glass; and
the joining comprises fusing a surface of the first piece of glass to a surface of the second piece of glass.
